(19) United States
(12) Patent Application Publication
(10) Pub. No.: US 2010/0188109 A1
(43) Pub. Date: Jul. 29, 2010

(54) ELECTRODE SYSTEMS AND THEIR USE IN THE CHARACTERIZATION OF MOLECULES

(76) Inventors: Joshua Edel, London (GB); Tim Albrecht, London (GB)

Correspondence Address: PATTERSON & SHERIDAN, L.L.P., 3040 POST OAK BOULEVARD, SUITE 1500, HOUSTON, TX, 77056, US

(21) Appl. No.: 12/519,344

(22) PCT Filed: Dec. 13, 2007
(86) PCT No.: PCT/GB2007/004796

§ 371 Date: Mar. 19, 2010

(30) Foreign Application Priority Data
Dec. 15, 2006 (GB) 0625070.8

(51) Int. Cl. G01N 27/04; B05D 5/12; G01N 15/10; H05K 1/00; G01R 27/08

(52) U.S. Cl. 324/693; 427/58; 174/250

(57) ABSTRACT

A method of characterizing a molecule comprises providing two electrodes (16a, 16b) which define a tunnelling gap between them; applying a potential difference between the electrodes; passing the molecule through the tunnelling gap; and measuring the tunnelling current between the electrodes over a measuring period, wherein at least a part of the molecule is within the gap for at least a part of the measuring period.

The present invention relates to the characterization of molecules. It has particular application in the analysis and sequencing of polymeric materials, such as DNA.

There has been considerable interest recently in the development and application of microfluidics or lab-on-a-chip technology. These microscale analytical instruments employ micromachined features (such as channels, electrodes, reactors, and filters) and are able to manipulate fluid samples with high precision and efficiency. Microfluidic chip devices have been used in a wide variety of applications including nucleic acid separations, proteomics, DNA amplification, DNA sequencing, and cell manipulations. In a fundamental sense, chip-based analytical systems have been shown to have many advantages over their conventional (larger) analogues. These include improved efficiency with regard to sample size, response times, cost, analytical performance, process control, integration, throughput, and automation.

More recently, there has been interest in scaling down microfluidic systems to create features such as channels with cross-sectional dimensions of a fraction of a micron. Such ‘nanofluidic’ devices open up new opportunities for fundamental and applied studies of nanofluidic phenomena. In basic terms, nanofluidics describes fluid flow in and around structures of nanoscale dimensions, arbitrarily defined as dimensions smaller than 100 nm. A number of defining characteristics separate fluid flow at the nanoscale from flow in larger environments. First, flow occurs in structures which are comparable to natural scaling lengths, e.g. the Debye length in electrolyte solutions. Second, the surface area-to-volume ratio can be enormous. Third, diffusion becomes an extremely efficient mass transport mechanism at this scale and finally the ultra-small volumes associated with nanofluidic environments allow effective confinement of analyte molecules to defined regions and thus theoretically allow 100% detection efficiencies. All of these characteristics can be exploited to significant advantage when processing or analyzing chemical and biological systems.

When compared to well-established techniques used in colloid science and membrane fabrication, which allow the formation of nanoscale features (such as pores) arranged in a random fashion, nanostructuring enables the formation and control of individual nanostructures of variable dimensions, geometry and location. In simple terms, nanochannels are defined as channels with at least one cross sectional dimension in the nanometer range. 1-dimensional nanochannels possess one sub-micron cross-sectional dimension, whilst 2-dimensional nanochannels have a both a depth and average width measured in nanometers. Such nanoscale dimensions allow the investigation of new phenomena, since the channel depth or width have similar size dimensions to that of the atoms or molecules dispersed within the fluid. Consequently, fundamental phenomena such as fluid transport and molecular behaviour within these ultra-low volume environments are extremely attractive and timely for investigation. From an application point of view, nanofluidic analysis systems represent a significant development, when compared to established microfluidic technologies, as enormous potential is offered for improvements in analytical efficiencies, sample throughput, and rare event detection. For example, there has recently been reported the use of two-dimensional nanofluidic channels to detect individual nucleic-acid-engineered fluorescent labels and quantum dot-biomolecule conjugates in free solution.

The present invention has particular application in nanofluidic devices for high-throughput polymer fragment sizing, monomer sequence analysis at the single molecule level, and rare molecule event analysis. Single molecule-based fragment sizing approaches have previously been developed in devices involving small capillaries and flow cytometry to analyze DNA. Moreover, single molecule DNA fragment sizing has also been demonstrated in microchannel environments. In these situations, channel dimensions are still fairly large, and thus restrictions are imposed on the optimal resolution that can be obtained, achievable analytical throughput and molecular detection efficiencies. For example, large channel dimensions require relatively large observation windows for uniform illumination of the entire channel width. Therefore, only slow flow speeds, or low sample concentrations, can be employed to avoid multiple molecular occupancies. Second, the larger the channel the greater noise contributions become from buffer solutions. With smaller channel dimensions, it can be ascertained that all of the DNA molecules passing the detection region will be analyzed rapidly and with high signal-to-noise ratios. Furthermore, the use of lithographic fabrication techniques makes it possible to create large arrays of devices to provide for high-throughput measurements at the single molecule level.

Accordingly the present invention provides a method of characterizing a molecule comprising: providing two electrodes which define a tunnelling gap between them; applying a potential difference between the electrodes; passing the molecule through the tunnelling gap; and measuring the tunnelling current between the electrodes over a measuring period, wherein at least a part of the molecule is within the gap for at least a part of the measuring period.

The present invention further provides method of characterizing a polymer molecule comprising: providing two electrodes which define a gap between them; applying a potential difference between the electrodes; passing the polymer molecule through the gap so that parts of the molecule pass between the electrodes in the order in which they are located along the molecule; and measuring the current between the electrodes as the molecule passes between them. The tunnelling currents are measured perpendicular to the polymer backbone.

The parts of the molecule may be monomers or other sub-units of the molecule.

The gap may be less than 10 nm and in some cases may be less than 5 nm.

The molecule may be a polymer, in which case the characterization may comprise determining the sequence of monomers or bases in the polymer. Alternatively the molecule may be a non-polymeric molecule.

The method may further comprise guiding the polymer so that parts of the polymer pass through the gap sequentially in the order in which they are located along the molecule. For example the molecule may be passed through a pore and the electrodes may be located relative to the aperture so that the molecule is guided between them as, or after, it passes through the pore.

The present invention further provides apparatus for characterizing molecules comprising a pair of electrodes defining a tunnelling gap between them across which a tunnelling current can flow, and guide means arranged to guide the molecules between the electrodes.

The present invention further provides apparatus for characterizing polymeric molecules comprising a pair of electrodes defining a gap between them across which a current can flow, and guide means arranged to guide the molecules between the electrodes so that parts of the molecule pass between the electrodes in the order in which they are located along the molecule.

The gap may be less than 10 nm, and in some embodiments is less than 5 nm.

The guide means may define a duct through which the molecules can flow while in solution. The guide means may be formed from a body of material having a pore formed through it.

The duct, or pore, may be less than 10 nm in diameter at the narrowest point along its length, and in some embodiments less than 5 nm in diameter.

The present invention still further provides a method of manufacturing apparatus for characterizing molecules, the method comprising: providing a layer of material having an aperture through it and having a pair of electrodes located on opposite sides of the aperture; reducing the size of the aperture; and reducing the size of the gap between the electrodes until it reaches a size at which a tunnelling current can flow between the electrodes.

The present invention yet further provides a method of manufacturing an electrode system, the method comprising: providing a layer of material having an aperture through it and having an electrode located adjacent to the aperture; and depositing conductive material onto the electrode.

The present invention still further provides an electrode system comprising a layer of material having an aperture through it and an electrode formed on the material, wherein the electrode is formed on a surface of the material adjacent to the aperture, and extends into the aperture.

According to some embodiments of the invention there are provided chemical and semiconductor processing methods to create nanofluidic devices for high-throughput DNA quantification at the single molecule level. Such systems may function by feeding DNA strands through nanoholes on a silicon nitride membrane.

Preferred embodiments of the present invention will now be described by way of example only with reference to the accompanying drawings in which:

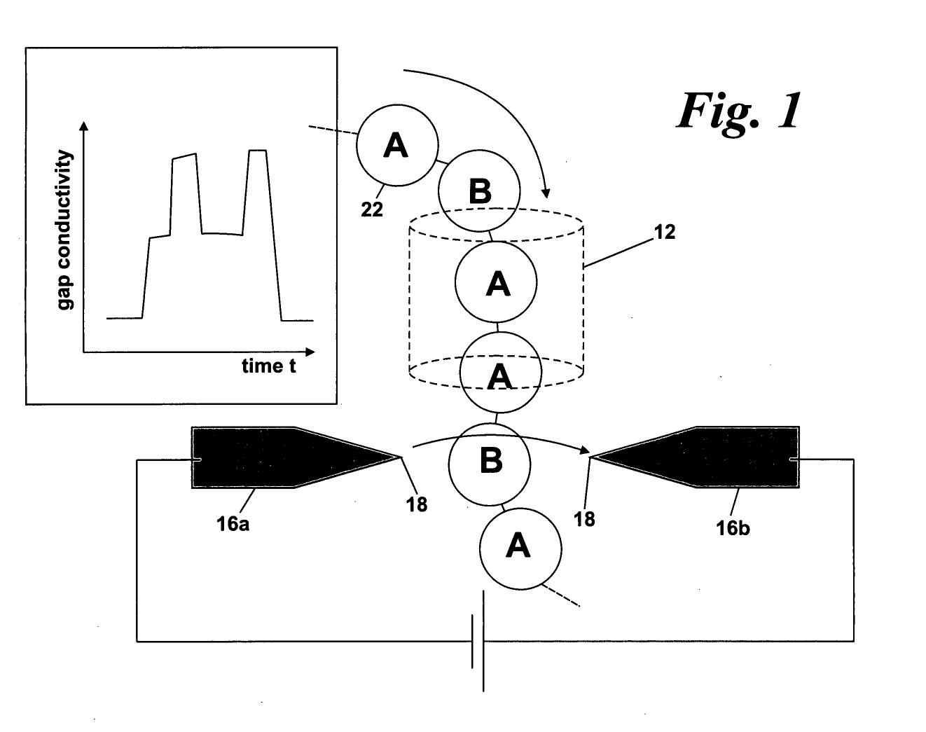

FIG. 1 is a schematic diagram of an apparatus according to an embodiment of the invention for characterizing molecules;

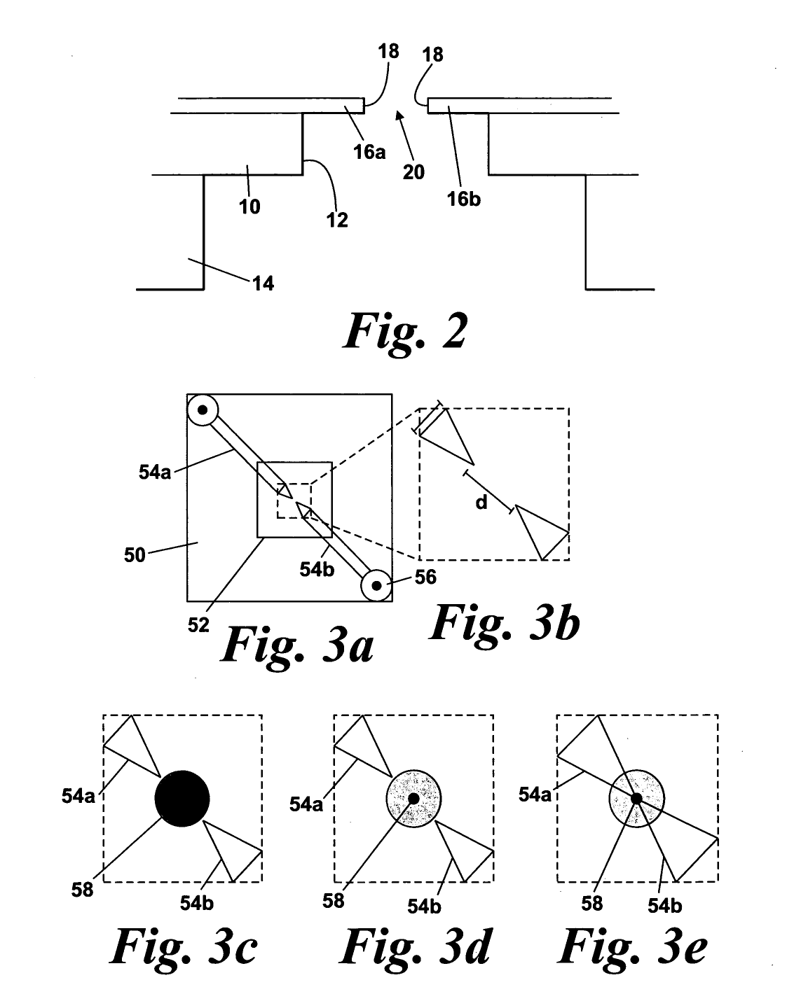

FIG. 2 is a section through part of the apparatus of FIG. 1;

FIGS. 3a to 3e show various steps in a method of manufacturing the apparatus of FIG. 1;

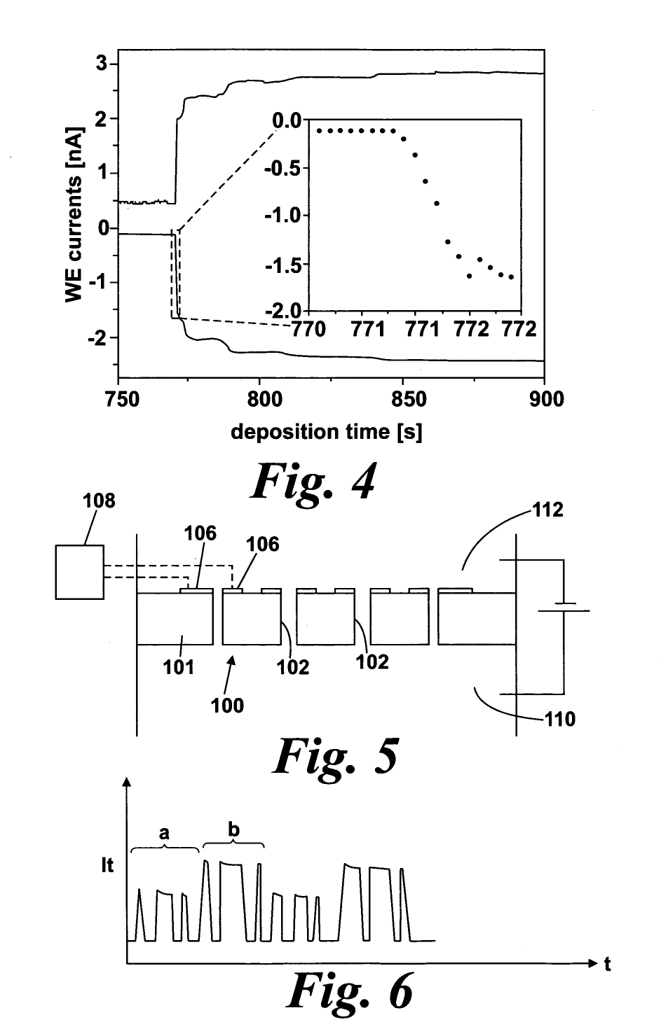

FIG. 4 is a graph of tunnelling current as a function of deposition time during deposition of the electrodes of the apparatus of FIG. 1; and

FIG. 5 is a diagram of a system according to a second embodiment of the invention;

FIG. 6 is a plot of tunnelling current as a function of time in the system of FIG. 5;

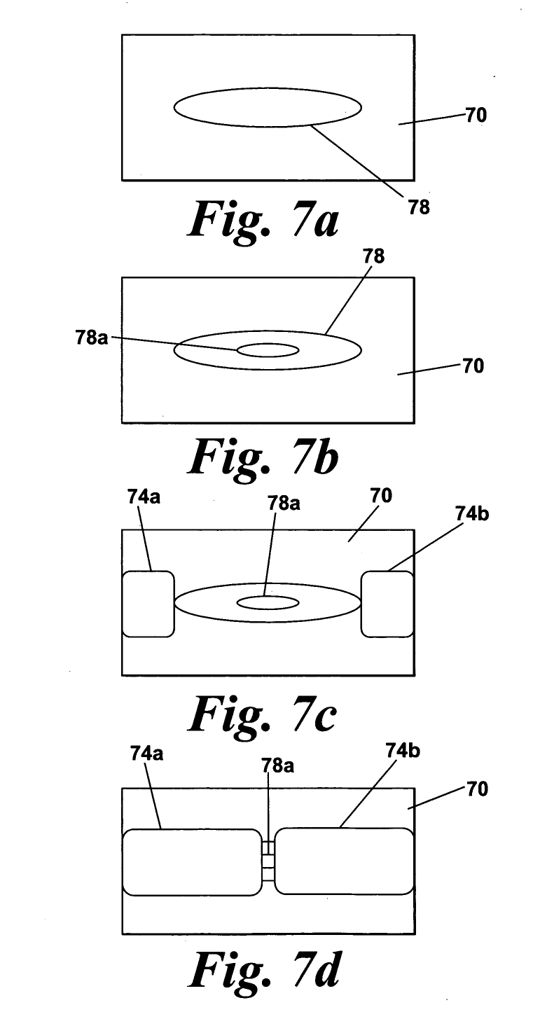

FIGS. 7a to d show various steps in a method of manufacturing an apparatus according to a further embodiment of the invention;

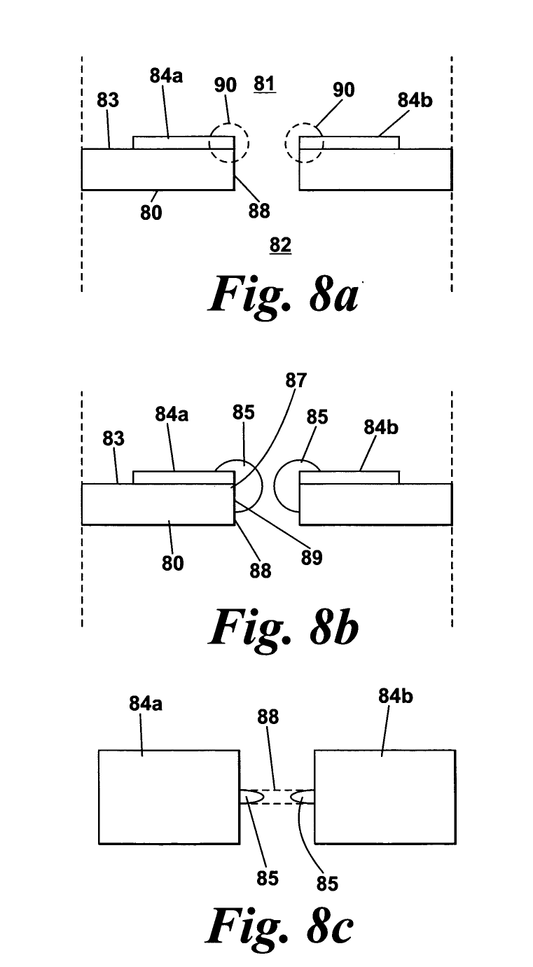

FIGS. 8a, 8b and 8c show two steps in a method of manufacturing an apparatus according to a further embodiment of the invention;

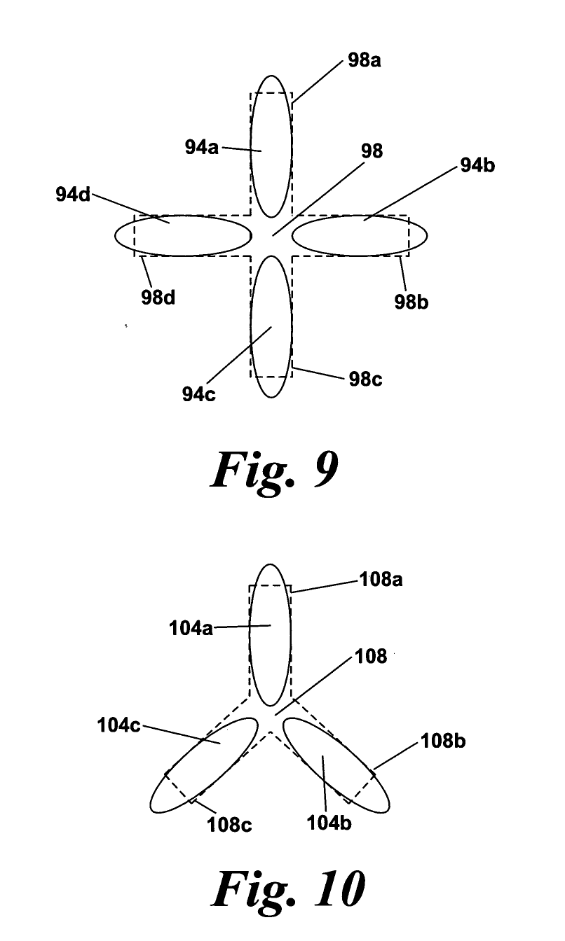

FIG. 9 is a plan view of an apparatus according to a further embodiment of the invention; and

FIG. 10 is a plan view of an apparatus according to a further embodiment of the invention.

Referring to FIGS. 1 and 2, a system for characterizing molecules comprises a layer 10 of non-conductive material, such as silicon nitride, having a nanohole or nanopore 12 formed through it. The layer of silicon nitride has a thickness of 20 to 200 nm and is supported on a silicon substrate 14 which has a thickness of 100 to 500 μm. The diameter of the nanopore is 1 to 10 nm at its narrowest point, preferably 1 to 5 nm and more preferably 1 to 2 nm. A pair of platinum electrodes 16a, 16b is formed on the surface of the silicon nitride layer on opposite sides of one end of the nanopore 12. The electrodes are shaped such that they each taper towards a fine tip 18, and the width of the gap 20 between the tips 18 of the two electrodes is from 1 to 5 nm, and preferably about the same as, or slightly greater than, the width of the nanopore 12.

The system is arranged to characterize molecules, typically polymers, which are transported electrophoretically or hydrodynamically through the pore 12. The polymers, which may for example be biopolymers (oligonucleotides, DNA, RNA, polypeptides, proteins, and enzymes) or synthetic polymers (copolymers), are in solution generally present in a folded, non-linear form. Each molecule 22 is transported towards the upstream end of the pore 12 where it unfolds and travels through the pore 12 in its linear unfolded state. Unfolding may be promoted by, for example, choice of solvent pH or polarity, denaturants, detergents or ligand binding. At the downstream end of the pore, the polymeric chain moves through nanometer-scale gap between the two conducting electrodes 16a, 16b, which are, further, held at a potential difference V_{bias}. The small nanometer size of this gap allows electrons to be transferred from one electrode to the other with a tunnelling current.

In solution, the individual potentials of electrodes 16a and 16b, E₁ and E₂, are controlled with respect to a reference electrode (bi-potentiostatic mode), which allows one to independently modulate the bias voltage V_{bias}=E₂−E₁ at constant E₁ (by varying E₂) or the absolute potentials E₁ and E₂ at constant V_{bias} (by varying E₁ and E₂ at the time). The tunnelling conductance G=Iₜ/V_{bias} in the gap then depends on the conductivity of the medium in the gap, V_{bias}=E₂−E₁, the tunnelling distance d between the electrodes 16a, 16b, and the electrode potentials E₁ and E₂.

At given values for V_{bias}, d, E₁ and E₂, the conductance G exclusively depends on the conductivity of the medium in the gap. The gap conductance G is recorded as a function of time t. Before the polymeric chain enters the pore, and the tunnelling gap, the conductance G is governed by the solvent and its electronic structure which is substance specific. When the chain enters the gap, G will be modulated according to the now combined conductivity of the solvent and the polymer chain. Furthermore, due to the strong distance dependence of the tunnelling effect, the tunnelling current is confined to the outermost atoms of the two electrodes 16a, 16b; cf. Scanning Tunnelling Microscopy (STM). This implies that the gap conductance is measured along the shortest way across the gap, with sub-nanometer resolution. Thus the tunnelling current, and hence the conductance, is measured in the direction transverse to the molecule. This is also the direction transverse to the pore 12. The measured conductance is therefore specific to the particular monomer within the polymer chain that is between the electrodes 16a, 16b, which enables monomer-specific differentiation within the polymer chain. If a certain monomer unit is exactly in between the two electrodes at a given point in time, the neighbouring units are already several nanometers away from the electrodes 16a, 16b, which is too far away from the electrodes to contribute significantly to G. This allows the system to distinguish different parts or monomers of the polymer chain down to a resolution of less than 10 nm and in most cases less than 5 nm in the axial direction of the pore, i.e. in the longitudinal direction along the polymer chain. This gives sufficient accuracy, for example, to determine the sequence of bases in a DNA molecule.

As shown in the example of FIG. 1, for a polymer made up of two different types A and B of monomer, as the monomers pass sequentially between electrodes 16a, 16b, the conductance, and therefore the tunnelling current between the electrodes will vary between a base level, which will be present before the polymer enters the gap, a first level which will be present whenever one of the monomer types A is between the electrodes, and a second level when the other of the monomer types B is between the electrodes. Because the polymer passes longitudinally, or lengthways, through the pore, the sequence in which the monomers pass through the pore and between the electrodes, corresponds to the sequence in which they are located along the molecule. The tunnelling current in the transverse direction through each of the monomers in turn is therefore measured. Therefore a plot of tunnelling current as a function of time will enable the sequence of the monomer types within the polymer chain to be determined.

Referring to FIGS. 3a to 3e, in one method of fabricating the device of FIG. 1, commercially available transmission electron microscope (TEM) grid structures are employed as platforms. These comprise a layer 50 of silicon nitride of 20 to 200 nm in thickness supported on a silicon platform of 100 to 500 μm and extending over an aperture 52, which is in this case 100 to 500 μm square, in the silicon platform. A pair of lithographically prepared electrodes 54a, 54b, for example Au or Pt, are formed on the silicon nitride layer facing each other, with macroscopic wire contacts 56 at the perimeter of the platform. The gap d between the two electrodes amounts to approximately 50 to 200 nm initially. The chip surface is then covered with an insulating film such as silicon nitride, Si₃N₄, except for an open window of about 5 μm×5 μm around the electrode gap, restricting electrochemical activity to the latter area as shown in FIG. 3a.

Referring to FIG. 3c, using focused ion beam (FIB) etching, a pore 58 is then fabricated in the electrode gap with a diameter of up to 200 nm, depending on the size of the electrode gap (step B). Employing FIB etching in another subsequent step, the large pore is melted beginning at its edges, until the overall pore diameter is decreased to below 5 nm as shown in FIG. 3d. These FIB etching steps can instead be carried out using TEM.

In the final step as shown in FIG. 3e, electrodeposition is used to narrow the electrode gap d to small nanometer separations, namely until a detectable tunnelling current arises between the electrodes at given V_{bias}.

During the electro-deposition process, the gap between the two tunnelling electrodes decreases, as more material is deposited either on one or on both electrodes simultaneously. Eventually, this gap will become small enough that, at a given potential difference V_{bias} between the electrodes, electrons can tunnel from one electrode to the other. In order to stop the process at a pre-defined gap size, different schemes can be used that rely either on the tunnelling current or the potential difference between the electrodes as trigger signals. Self-termination schemes have been developed which rely on breaking a conductive strip to leave to electrodes separated by a suitable gap, either by heating a restriction in the strip until it melts, or by bending the conductive strip until it breaks.

In this embodiment the two platinum working electrodes WE1 and WE2 are, for example, held at respective potentials E(WE1)=−0.3 V, and E(WE2)=−0.2 V, giving a bias voltage between the two electrodes of V_{bias}=−0.1 V, in a solution of 0.01 M K₂[PtCl₄] in 0.1 M HClO₄.

Referring to FIG. 4, as the electro-deposition takes place and the gap between the electrodes narrows, the deposition current on the second electrode WE2 remains constant until the gap becomes very small and tunnelling sets in, causing a sharp increase in the tunnelling current which can be seen to occur at about 770 s deposition time in FIG. 4. This sharp increase around the onset of tunnelling current is shown enlarged on an expanded time axis in FIG. 4. If electro-deposition is allowed to continue, as the gap closes further, aggregates form in the gap and modulate the tunnelling current in a step-wise fashion (due to quantum-size effects). Once the gap is completely closed, the junction behaves like an Ohmic resistor. This occurs at about t=850 s in FIG. 4.

In this embodiment, the sharp increase in tunnelling current is detected and used as a trigger to stop the electro-deposition process, which sets the tunnelling gap such that a tunnelling current can pass between the electrodes.

The process is described above for one pore, but fabrication of massively parallel devices, in which a single layer of material such as silicon nitride, has a large number of pores formed in it, each with a respective pair of electrodes, can be performed in a similar manner.

Furthermore, while one electro-deposition strategy is described above, many more have been developed for Pt and other metals which can also be used. The electro-deposition process can involve the original electrode materials, but can also be used to deposit different substances onto the original electrodes to modify their properties and tunnelling characteristics. In particular in some applications surface-enhanced Raman spectroscopy (SERS) active metals, such as Au, Ag, Pt, and Cu can be used as the coating material deposited on the electrodes so that they form the surface of the finished electrodes.

A number of alternative routes have also been devised to fabricate nanometer scale electrode gaps, including scanning probe techniques, break-junctions, e-beam lithography, and electromigration. All of these can be used in the present invention. However, for the embodiment of the present invention described above, lithography combined with electro-deposition is most suitable, for the reasons outlined below.

Scanning probe techniques, namely scanning tunnelling microscopy (STM) and current-sensing atomic force microscopy (CS-AFM), both in air and in liquid, have proven to be powerful tools for the study of single-molecule conductivity, with the molecule in question attached either to one only or both electrodes (the STM tip, the AFM cantilever, or the substrate surface). The molecular conductivity is thus measured along the molecular axis. The tunnelling gaps are, however, not very stable in time and it is therefore not possible to integrate such a system with a pore configuration, as required for the embodiments of the invention described above. It should also be noted that the conductivity of the tunnelling gap in these embodiments is measured perpendicular to the molecular backbone, in contrast to previous STM/CS-AFM studies.

In the break-junction approach, a metallic wire is deposited onto a chip substrate which is then bent with an appropriate mechanism (often based on a piezo crystal). The wire will eventually break leaving a sometimes sub-Angstrom-sized gap between the two parts of the wire. Still being under mechanical control, the gap size can then be modulated by changing the degree of substrate bending. In preferred embodiments of the present invention, however, the pore/electrode configuration is too complex to employ this approach. Bending of the substrate induces strain on the pore which is likely to cause, first, deformation of the pore itself, and secondly, mechanical failure due to the composite nature of the present invention.

Sophisticated e-beam lithographic techniques have occasionally been able to produce electrode pairs with small nanometer gap sizes. Again the technique is less suited for the present invention, as the cost per electrode/pore architecture is much higher and the absolute precision, in terms of a total success ratio, using this fabrication scheme is not high enough.

Electromigration is another technique to manufacture nanometer scale electrode gaps. Breaking of the wire at a pre-defined constriction is caused by resistive heating from an electric current flowing through the wire. While this approach appears simpler than electrodeposition, at first glance, it is again very difficult to integrate the nanoscale gap with the pore architecture. While electromigration provides good control over the gap size, the exact alignment of the latter with the pore is not possible to sufficient precision.

Referring to FIG. 5, in a further embodiment of the invention a chip 100 comprises a layer of support material 101, which may be supported on a substrate layer, having a large number of pores 102 extending through it from one side to the other. On one side 104 of the support material 101 a pair of electrodes 106 is provided on opposite sides of each of the pores 102. The pores and electrodes are similar to those of FIGS. 1 to 3 and will not be described in detail. A controller 108 is connected to each of the electrodes so that it can measure and monitor the tunnelling current across each pair of electrodes as a function of time. The chip is supported between two reservoirs 110, 112 which are filled with a solvent carrying molecules to be analysed, such as DNA fragments. A DC voltage is applied between the two reservoirs, in a known manner by providing an electrode in each reservoir, and this voltage drives the DNA fragments through the pores 102 by electrophoresis. While this is happening, the controller 108 measures and records the electrical current between each pair of electrodes as a function of time. It will be appreciated that, in this type of system, very large numbers of pores can be provided, for example at least 100, or at least 1000, or in some cases at least 10,000, in a single chip which can provide massively parallel analysis of large numbers of molecules.

In this way all, or at least substantially all, of the molecules in the solution can be analysed individually. This enables analysis or detection of rare events. For example if a very small fraction of the molecules have a different monomer sequencing, for example if they include additional monomers or have one or several less monomers than the rest of the molecules this can be detected. Alternatively a solution containing a mixture of different types of molecule can be ‘searched’ to check whether one or more molecules having a particular characteristic is present.

Rather than using electrophoresis, the molecules can be moved through the pores hydrodynamically, i.e. by moving the solvent through the pores such that the molecules to be analysed are transported with the solvent. As a further option diffusion can be used, especially for smaller molecules.

It will be appreciated that the variation in tunnelling current measured as a molecule, or a part of a molecule, passes through between a pair of electrodes will vary significantly depending on the type of molecule. Referring to FIG. 6 in this embodiment there are two types of monomer in the polymer as in the example of FIG. 1. As each monomer passes between the electrodes a highly varying current is measured, the current having various characteristics or parameters that depend on the nature of the monomer. As can be seen, the current has a series of peaks or pulses for which parameters including amplitude, frequency, and length (in the time domain) can be determined by the controller 108. In the example shown a first group of peaks a having a first amplitude are produced as a first monomer type passes between the electrodes, and a second group of peaks b having a second amplitude are produced as a second monomer type passes between the electrodes. The controller 108 is arranged to analyse the tunnelling current to identify the periods when the different monomers are passing between the electrodes, and to identify the individual monomers based on the characteristics of the current during those periods.

In another embodiment similar to that of FIG. 5, the controller is arranged to identify the times at which each of the ends of the polymer pass through the tunnelling gap, and determines the length of the DNA molecule or fragment based on the time taken for the molecule to pass through the gap and the speed at which the molecule is travelling. That speed can be determined by measuring the time taken for molecules of known length to pass between the electrodes.

In a further embodiment similar to that of FIG. 5, the power supply that provides the voltage to the electrodes to drive the molecules through the pores is pulsed. For example it may be pulsed on and off between a driving voltage and zero, or it may be pulsed between two or more different voltages. This is arranged to cause the molecules to move through the pores in steps, with each step followed by a period during which the molecule is substantially stationary. The controller 108 is arranged to control the timing of these pulses and is therefore also arranged to measure the tunnelling current between each of the electrode pairs during each of the periods when the driving voltage is zero and the molecule is substantially stationary. By controlling the magnitude and duration and frequency of the pulses of driving voltage, the distance travelled at each step by the molecule can be controlled. This can allow control of the position along the molecule at which the tunnelling current is measured and hence the characteristics of the molecule are determined. It will be appreciated that the driving voltage can be varied and controlled in a number of ways to control the speed at which the molecule progresses through the pore and between the electrodes. By controlling the AC field the translation of a molecule through the nanopore may be effectively halted.

While the embodiments described above all have one pair of electrodes associated with each pore, in some cases more than two electrodes can be provided for each pore. There can be equal numbers of anodes and cathodes, or different numbers of anodes and cathodes, and the electrodes can be spaced around the end of the pore so that the tunnelling current in different transverse directions across the pore can be measured.

Referring to FIGS. 7a to 7d, in a further embodiment of the invention the device is made in a manner similar to that of FIGS. 3a to e, but with a pore and electrodes of different shapes. Referring to FIG. 7a, a silicon nitride layer 70 of about 50-200 nm thickness is again supported on a silicon platform of about 300 μm which has an aperture through it. An aperture 78 is again formed through the silicon nitride layer 70, but in this case it is long and narrow, in the form of a slit 78 of 20 nm by 200 nm. The slit 78 is then reduced in width to a smaller size 78a of about 5 nm and in length to around 185 nm by silicon oxide deposition as shown in FIG. 7b. Two electrodes 74a, 74b are formed at the two ends of the slit 78 as shown in FIG. 7c. This can be done before or after the slit has been reduced in size. The electrodes are arranged to be significantly wider than the slit 78 so that accurate location in the direction transverse to the slit is not required. The electrodes 74a, 74b are then grown by electro-deposition so that they grow along the slit 78 towards each other and the gap between them reduces in size. When the gap between the electrodes 74a, 74b reaches the desired size, as shown in FIG. 7d, the electro-deposition is stopped.

It will be appreciated that, with this arrangement of slit aperture 78 and wide electrodes 74a, 74b, the problem of alignment of the electrodes with the final aperture is simpler than in the embodiment of FIGS. 3a to 3e.

Referring to FIGS. 8a to 8c, in a further embodiment a narrow slit 88, with a width of the order of 10 nm or less, is formed in the silicon nitride layer 80, and two electrodes 84a, 84b are formed on the surface 83 of the layer 80 adjacent to the ends of the slit 88. In this case the starting platform consists of a 300 μm thick 5×5 mm silicon substrate. Silicon nitride is deposited on the substrate using low-pressure chemical vapour deposition (LPCVD) at a temperature of 825° C. and ammonia and dichlorosilane gases to produce a total thickness of 50-200 nm. The ratio of flow rates for ammonia and dichlorosilane is approximately 1:5. This results in a silicon-rich nitride film, with a tensile stress in the range of 50-150 MPa. This stress is low enough to allow the formation of free standing membranes. A 5 μm×5 μm window is then fabricated on the silicon substrate wafer using photolithography and KOH wet etching. An elliptical pore or slit is drilled into a Si₃N₄ membrane using a focussed ion beam (FIB) or a scanning tunnelling electron microscope (STEM). Typical slit geometries can vary between 20×500 nm in width and 20-5000 nm in length. For example, 20×200 nm sized elliptical holes can be milled in a sequential fashion using an FIB at 30 kV and 20 pA with exposure times ranging from 1-10 s. Therefore a complete slit can be drilled through the membrane within a 60 s time frame.

This slit can be narrowed by isotropically depositing SiO₂ either via a plasma enhanced chemical vapor deposition process (PECVD) or via a SEM/FIB TEOS process. This step allows for the size along the short axis to be reduced to about 5 nm.

A pair of opposing platinum electrodes with a gap width of ˜500 nm-10,000 nm is deposited and patterned using a combination of thermal evaporation and resist lift-off techniques, on the planar top surface of the membrane adjacent to the slit. Alignment of the slit and electrodes can be performed with carefully designed alignment markers. At their ends, the electrodes will have a thickness of the order of 50 nm and a width of the order of 100 nm. Alternatively it is possible to deposit electrodes prior to the slit fabrication and to introduce a potentially simpler alignment mechanism.

The layer 80 is positioned between two reservoirs 81, 82 the contents of which can be controlled as required.

For the electro-deposition onto the electrodes, the reactants from which the deposits onto the electrodes are obtained are provided in higher concentration in the lower reservoir 82, on the opposite side of the layer 80 to the electrodes 84a, 84b, than in the upper reservoir, on the same side as the electrodes 84a, 84b. The concentration of reactants in the upper reservoir is in fact kept as low as possible. In this case this is achieved by introducing the reactants only into the lower reservoir 82 and not into the upper reservoir 81.

During electro-deposition the metal from the reactants is deposited onto the surface of the electrodes at a rate which is determined in part by the concentration of reactants at the surface of the electrodes. In this case, the concentration increases rapidly from the upper side of the slit 88 to the lower side. This means that the deposition occurs most rapidly on the parts of the electrodes closest to the slit 88, and within the slit 88 on the parts of the electrodes closest to the bottom of the slit 88. This results in the electrodes 84a, 84b growing by the deposition of conductive material 85 in the region 90 at the top of the slit 88, and growing over the rim 87 of the slit 88, and down the side 89 of the slit and into the slit 88 as shown in FIG. 8b. As can also be seen in FIG. 8c, the part 85 of the electrodes 84a, 84b that grows down into the slit 88 is obviously constrained by the size of the slit 88, and therefore these parts fill the entire width of the slit 88 and grow along it towards each other, and downwards into the slit. The result is electrodes which have a very high aspect ratio.

As can be seen in FIGS. 8b and 8c, the narrowest part of the gap between the electrodes 84a, 84b after the electro-deposition is completed is below the top surface of the electrodes 84a, 84b, and may also be below the top surface 83 of the layer 80. This ensures that molecules moving through the slit 88 have to pass through the narrowest part of the gap between the electrodes 84a, 84b.

It will be appreciated that in this arrangement the alignment of the slit 88 and the electrodes 84a, 84b after they have been grown is very good because the electrode growth has been guided into the slit itself. This further helps to ensure that, when the device is used, for example, in a system similar to that of FIG. 5, the molecules being characterized cannot bypass the electrodes as they pass through the slits 88.

Referring to FIG. 9, in a further embodiment the aperture 98 is cross shaped, being formed of four narrow slits 98a, 98b, 98c, 98d extending outwards from a central point so that each has a closed end furthest from the centre and an open end where it is joined to the other slots. An electrode 94a, 94b, 94c, 94d is formed adjacent to, and extending into, each of the four slots using the same method as described above with reference to FIGS. 8a to 8c. This provides a four-electrode system which can be used, for example, for electrophoretic or dielectrophoretic trapping of molecules or polymers in the electrode gap using two opposing electrodes, where the other set of opposing electrodes is used for tunnelling current-based analysis of the trapped species. The trapping approach is also applicable to electrode gaps, which are too large for a tunnelling current to flow; analysis will then have resort to other techniques, for example based on single molecule fluorescence spectroscopy. It is envisaged that an electric field can oscillate in this quadrupolar electrode arrangement.

Referring to FIG. 10, in a further embodiment, the aperture 108 is made up of three slots 108a, 108b, 108c radiating form a central point, with an electrode 104a, 104b, 104c formed in each of them, giving a Y-shaped arrangement. We envisage that, in this configuration, two electrodes can be used for tunnelling current-based analysis of translocating species, whereas the third electrode is used as local gate, similar to an electronic transistor. Depending on the local gate field, different electronic levels of the translocating species can be brought to interact with the two tunnelling electrodes, providing additional means for characterization of the translocating molecule or polymer. Two electrodes could also be used for electrophoretic or dielectrophoretic trapping of molecules in the gap, which could then be probed by a tunnelling current between either of the two and the third electrode.

It will be appreciated that in the embodiments of FIGS. 8a-c, 9 and 10 the separate electrodes may be formed of the same material, or they may formed of different materials. Also, by applying electrical potentials to only one or some of the electrodes during the electro-deposition process they can be built up at different rates or by different amounts so that the resulting electrodes have different sizes or shapes as required depending on the application.

1-69. (canceled)

70. A method of manufacturing an electrode system, the method comprising:
providing a layer of material having an aperture through it and having an electrode located adjacent to the aperture; and
depositing conductive material onto the electrode.

71. A method according to claim 70, wherein the aperture has a length in one direction and a width in a perpendicular direction, and its length is greater than its width.

72. A method according to claim 71, wherein the aperture has an end and the electrode is located at the end of the aperture.

73. A method according to claim 72, wherein the aperture has a further end and a further electrode is provided at the further end of the aperture.

74. A method according to claim 72, wherein prior to the depositing of conductive material the electrode is wider than the aperture.

75. A method according to claim 70, wherein the layer of material is located between two reservoirs, and a reactant arranged to provide at least a component of the conductive material deposited on the electrode is provided in higher concentration in one of the reservoirs than the other.

76. A method according to claim 75, wherein the electrode is provided on one side of the aperture, and the reactant is provided in a higher concentration in the reservoir on the other side of the aperture.

77. A method according to claim 70, wherein the conductive material is deposited onto the electrode so that the electrode grows within the aperture.

78. A method according to claim 70, wherein the conductive material is deposited onto the electrode so that the electrode grows further in a first direction down into the aperture than in a second direction opposite to the first.

79. A method according to claim 70, wherein the conductive material is a SERS active material.

80. An electrode system comprising a layer of material having an aperture through it and an electrode formed on the material, wherein the electrode is formed on a surface of the material adjacent to the aperture, and extends into the aperture.

81. An electrode system according to claim 80, wherein the surface is substantially planar, and the aperture has a side surface and a rim between the planar surface and the side surface, and the electrode extends over the rim and onto the side surface of the aperture.

82. An electrode according to claim 80, wherein the aperture has a length and width, the length being greater than the width and two ends, the electrode being provided at one of the ends of the aperture and a further electrode being provided at the other end.

83. An electrode system according to claim 80, wherein the aperture comprises a plurality of connected slots each having an open end and a closed end, a respective electrode being provided at the closed end of each slot.
